(19) United States
(12) Patent Application Publication
(10) Pub. No.: US 2025/0062594 A1
(43) Pub. Date: Feb. 20, 2025

(54) SEMICONDUCTOR LASER AND METHOD FOR PRODUCING A SEMICONDUCTOR LASER

(71) Applicant: ams-OSRAM International GmbH, Regensburg (DE)

(72) Inventor: Hubert HALBRITTER, Dietfurt (DE)

(73) Assignee: ams-OSRAM International GmbH, Regensburg (DE)

(21) Appl. No.: 18/721,349

(22) PCT Filed: Nov. 18, 2022
(86) PCT No.: PCT/EP2022/082371

§ 371 Date: Jun. 18, 2024

(30) Foreign Application Priority Data
Dec. 20, 2021 (DE) 102021133904.9

(51) Int. Cl. H01S 5/11; H01S 5/02; H01S 5/042; H01S 5/20; H01S 5/30

(52) U.S. Cl. CPC H01S 5/11; H01S 5/0216; H01S 5/0217; H01S 5/04253; H01S 5/2027; H01S 5/3095

(57) ABSTRACT

Disclosed is a semiconductor laser with a vertical emission direction including a first active region and a first photonic crystal, wherein during operation of the semiconductor laser, first radiation emitted in the first active region is partially deflected into the vertical emission direction by means of the first photonic crystal, a second active region and a second photonic crystal, wherein during operation of the semiconductor laser, second radiation emitted in the second active region is partially deflected into the vertical emission direction by means of the second photonic crystal, and a connection region which is arranged in the vertical emission direction between the first active region and the second active region and connects the first active region and the second active region together in an electrically conductive manner. Also disclosed is a method for producing a semiconductor laser.

### CROSS-REFERENCE TO RELATED APPLICATIONS

The present application is a national stage entry from International Application No. PCT/EP2022/082371, filed on Nov. 18, 2022, published as International Publication No. WO 2023/117232 A1 on Jun. 29, 2023, and claims priority to German Patent Application No. 10 2021 133 904.9, filed Dec. 20, 2021, the disclosures of all of which are hereby incorporated by reference in their entireties.

### FIELD

The present application relates to a semiconductor laser and a method of manufacturing a semiconductor laser.

### BACKGROUND

Semiconductor lasers can be used to generate laser radiation in which the radiation propagating in the layer plane of the semiconductor material is deflected via a photonic crystal in a direction vertical to the layer plane. Such semiconductor lasers are also known as PCSELs (photonic crystal surface emitting lasers).

Although such semiconductor lasers comprise a good beam quality, they typically have a lower optical power density than edge-emitting semiconductor lasers, as the radiation is emitted through a larger emission area at the same operating current.

An object is to specify a semiconductor laser that emits radiation with good beam quality and a high optical power density during operation. Furthermore, a method is to be specified with which a semiconductor laser can be manufactured efficiently and reliably.

These objects are achieved, inter alia, by a semiconductor laser or a method according to the independent claims. Further configurations and expediencies are the subject of the dependent claims.

### SUMMARY

A semiconductor laser with a vertical emission direction is specified. During operation of the semiconductor laser, the radiation therefore exits through a radiation exit surface of the semiconductor laser that runs parallel to a layer plane of the semiconductor layers of the semiconductor laser. The radiation is, for example, in the ultraviolet, visible or infrared spectral range.

According to at least one embodiment of the semiconductor laser, the semiconductor laser comprises a first active region and a first photonic crystal.

During operation of the semiconductor laser, a first radiation emitted in the first active region is partially deflected in the vertical emission direction by means of the first photonic crystal. In particular, the first radiation propagates in a lateral direction in a first waveguide.

A photonic crystal is based in particular on interference and/or diffraction effects on a structure with a refractive index curve that changes periodically along one, two or three directions in space. The period is adapted to the wavelength of the radiation to be deflected.

For example, the first active region is located between a first n-conducting semiconductor layer and a first p-conducting semiconductor layer, so that the first active region is arranged in a pn junction.

For example, a first waveguide is formed by means of the first n-conducting semiconductor layer and the first p-conducting semiconductor layer, in which the first radiation propagates in a lateral direction, i.e. a direction perpendicular to the vertical emission direction, during operation of the semiconductor laser.

Radiation propagating in the first waveguide can be coupled out in the vertical emission direction via the first photonic crystal.

According to at least one embodiment of the semiconductor laser, the semiconductor laser comprises a second active region and a second photonic crystal.

During operation of the semiconductor laser, second radiation emitted in the second active region is partially deflected in the vertical emission direction by means of the second photonic crystal. In particular, the second radiation propagates in a lateral direction in a second waveguide.

For example, the second active region is located between a second n-conducting semiconductor layer and a second p-conducting semiconductor layer, so that the second active region is arranged in a pn junction.

For example, a second waveguide is formed by means of the second n-conductive semiconductor layer and the second p-conductive semiconductor layer, in which the second radiation propagates in the lateral direction during operation of the semiconductor laser.

Radiation propagating in the second waveguide can be coupled out in the vertical emission direction via the second photonic crystal.

The first active region and/or second active region comprises in particular a quantum structure.

In the context of the application, the term quantum structure includes in particular any structure in which charge carriers can undergo quantization of their energy states by confinement. In particular, the term quantum structure does not include any indication of the dimensionality of the quantization. It thus includes, inter alia, quantum wells, quantum wires, quantum rods and quantum dots and any combination of these structures. For example, the first active region and/or the second active region comprise a multi-quantum well (MQW) structure with a plurality of quantum layers and barrier layers disposed between the quantum layers.

The active regions, the n-conducting semiconductor layers and the p-conducting semiconductor layers can each be mono-layer or multilayer.

According to at least one embodiment of the semiconductor laser, the semiconductor laser comprises a connection region arranged in the vertical emission direction between the first active region and the second active region. In particular, the connection region connects the first active region and the second active region to one another in an electrically conducting manner.

For example, the connection region provides complete or at least partial optical decoupling between the radiation propagating in the first waveguide and the radiation propagating in the second waveguide in the lateral direction. In particular, the connection region is located outside the first and second waveguide.

In at least one embodiment, the semiconductor laser having a vertical emission direction comprises a first active region and a first photonic crystal, wherein, during operation of the semiconductor laser, a first radiation emitted in the first active region is partially deflected in the vertical emission direction by means of the first photonic crystal. The semiconductor laser comprises a second active region and a second photonic crystal, wherein a radiation emitted in the second active region during operation of the semiconductor laser is partially deflected in the vertical emission direction by means of the second photonic crystal. A connection region of the semiconductor laser is arranged between the first active region and the second active region, wherein the connection region connects the first active region and the second active region to one another in an electrically conducting manner. In particular, the first radiation propagates in a lateral direction in a first waveguide and the second radiation propagates in a lateral direction in a second waveguide.

Seen along the vertical emission direction, the first active region and the second active region are therefore located one above the other. The first radiation and the second radiation can therefore exit through the same radiation exit surface and overlap completely or at least partially, so that the optical power density of the total radiation emitted by the semiconductor laser is increased, in particular at the same operating current.

Seen along the vertical emission direction, the first active region and the second active region may be located between a first contact and a second contact for external electrical contacting of the semiconductor laser. By applying an electrical voltage between the first contact and the second contact, charge carriers can be injected into the first active region and the second active region and recombine to emit first radiation and second radiation, respectively.

For example, the semiconductor laser comprises exactly two contacts, i.e. the first contact and the second contact.

Deviating from this, a third contact may be present, which electrically contacts the semiconductor laser between the first active region and the second active region. For example, the third contact is adjacent to the connection region. By means of such a third contact, the first active region and the second active region can be operated independently of each other and, for example, supplied with different operating voltages.

According to at least one embodiment of the semiconductor laser, a forward direction of the first active region and a forward direction of the second active region point in the same direction. In other words, the first active region and the second active region are arranged parallel and not antiparallel to each other with respect to their forward direction. For example, the first n-conducting semiconductor layer is arranged on the side of the first active region facing the radiation exit surface and the second n-conducting semiconductor layer is arranged on the side of the second active region facing the radiation exit surface. Alternatively, the first n-conducting semiconductor layer can be arranged on the side of the first active region facing away from the radiation exit surface and the second n-conducting semiconductor layer can be arranged on the side of the second active region facing away from the radiation exit surface.

This simplifies the electrical series connection of the first active region and the second active region. However, the forward direction of the first active region and the forward direction of the second active region can also run antiparallel to each other, particularly if a third contact is present.

According to at least one embodiment of the semiconductor laser, the first active region and the second active region are of the same type. In this context, of the same type means that the semiconductor layers of the first active region and the second active region differ from one another in terms of their layer thicknesses and their material composition at most within the scope of manufacturing-related fluctuations. In particular, the first active region and the second active region are configured such that a peak wavelength of the first radiation and a peak wavelength of the second radiation do not differ from each other or differ only slightly, for example by at most 10 nm.

According to at least one embodiment of the semiconductor laser, the first photonic crystal and the second photonic crystal are of the same type. In particular in conjunction with a first active region and a second active region, which are formed of the same type, a coupling, in particular a mode locking, can be achieved between the first radiation and the second radiation. This allows the semiconductor laser to generate radiation with a particularly high overall efficiency. However, this is not absolutely necessary. Alternatively, the semiconductor laser can be designed in a targeted manner such that the first radiation and the second radiation differ from each other in at least one property.

According to at least one embodiment of the semiconductor laser, the first radiation and the second radiation differ from each other along the vertical emission direction with respect to their polarization direction. For example, the polarization directions are perpendicular or essentially perpendicular to each other. The optical coupling between the first radiation and the second radiation can thus be minimized.

According to at least one embodiment of the semiconductor laser, the first active region and the second active region differ from each other with respect to a material composition. Due to different material compositions, different peak wavelengths can be generated for the first radiation and the second radiation. Alternatively or additionally, different peak wavelengths can also be achieved by different layer thicknesses of the quantum layers in the active regions.

For example, the first active region and the second active region are based on different compound semiconductor material systems.

For example, the first active region is based on a nitride compound semiconductor material and the second active region on an arsenide or phosphide compound semiconductor material or vice versa. As a result, a semiconductor laser can be achieved in which radiation components exit from the same radiation exit surface that comparatively strongly differ from each other in terms of peak wavelength. For example, the peak wavelength of the first radiation and the peak wavelength of the second radiation differ from each other by at least 20 nm or at least 50 nm or at least 100 nm.

In the present context, “based on nitride compound semiconductor material” means that the semiconductor material, in particular of an active region, comprises or consists of a nitride compound semiconductor material, preferably AlₓIn_{y}Ga_{1-x-y}N, where 0≤x≤1, 0≤y≤1 and x+y≤1. This material does not necessarily comprise a mathematically exact composition according to the above formula. Rather, it can comprise one or more dopants and additional components, for example. For the sake of simplicity, however, the above formula only contains the essential components of the crystal lattice (Al, Ga, In, N), even if these may be partially replaced and/or supplemented by small amounts of other substances.

In the present context, “based on arsenide or phosphide compound semiconductor material” means that the semiconductor material, in particular of an active region, comprises a compound semiconductor material with arsenic and/or phosphorus as a group V element, preferably comprising AlₓIn_{y}Ga_{1-x-y}P_{z}AS_{1-z}, where 0≤x≤1, 0≤y≤1, x+y≤1 and 0≤z≤1. This material does not necessarily comprise a mathematically exact composition according to the above formula. Rather, it may comprise one or more dopants and additional components, for example. For the sake of simplicity, however, the above formula only contains the essential components of the crystal lattice (Al, Ga, In, P, As), even if these may be partially replaced and/or supplemented by small amounts of other substances.

According to at least one embodiment of the semiconductor laser, the connection region is a tunnel junction. Via a tunnel junction, the first active region and the second active region can be integrated into a common epitaxial semiconductor layer sequence, wherein the tunnel junction effects an electrical series connection between the first active region and the second active region.

According to at least one embodiment of the semiconductor laser, the connection region comprises a TCO (transparent conductive oxide, “TCO” for short) material.

Transparent, electrically conductive oxides are transparent, electrically conductive materials, usually metal oxides such as zinc oxide, tin oxide, cadmium oxide, titanium oxide, indium oxide or indium tin oxide (ITO). In addition to binary metal-oxygen compounds, such as ZnO, SnO₂ or In₂O₃, ternary metal-oxygen compounds are also included, such as Zn₂SnO₄, CdSnO₃, ZnSnO₃, MgIn₂O₄, GaInO₃, Zn₂In₂O₅ or In₄Sn₃O₁₂ or mixtures of different transparent conductive oxides belong to the group of TCOs. Furthermore, it is possible that the TCOs do not necessarily correspond to a stoichiometric composition and can also be p- or n-doped.

The first active region and the second active region can be integrated into the semiconductor laser via a TCO material and, in particular, electrically contacted together, although the first active region and the second active region are produced separately from each other during the manufacture of the semiconductor laser, for example epitaxially deposited on separate growth substrates.

The first active region and the second active region can be based on the same semiconductor material system or on different semiconductor material systems.

According to at least one embodiment of the semiconductor laser, a reflector is arranged on a side of the first active region opposite the radiation exit surface. In particular, the first active region and the second active region are located between the reflector and the radiation exit surface. For example, the reflector comprises a reflectivity of at least 90% or at least 95% or at least 99%. The reflector can be designed as a Bragg reflector, a metal reflector, or a combination thereof. At the radiation exit surface, for example, the reflectivity is at most 50% or at most 20% or at most 10%.

During operation of the semiconductor laser, a standing wave field can form in the vertical emission direction.

According to at least one embodiment of the semiconductor laser, the connection region is arranged in a minimum of the standing wave field. Such minima in a standing wave field are also referred to as nodes. Absorption losses within the connection region can thus be minimized. For this purpose, the distances between the first active region and the second active region and/or the distances between the first active region and the reflector of the semiconductor laser and/or the distance between the second active region and the reflector can be adapted.

Furthermore, a method for manufacturing a semiconductor laser is specified. The method is particularly suitable for the manufacture of a semiconductor laser described above. Features described in connection with the semiconductor laser can therefore also apply for the method and vice versa.

In at least one embodiment of the method, the method comprises a step of providing a first active region and a first photonic crystal. Further, the method comprises a step in which a second active region and a second photonic crystal are arranged on the first active region, wherein a connection region is arranged between the first active region and the second active region. The connection region electrically conductively connects the first active region and the second active region to one another.

The first active region and the second active region are thus arranged stacked on top of each other along a vertical emission direction.

According to at least one embodiment of the method, the second active region is deposited separately from the first active region on an initial carrier. The initial carrier is, for example, a growth substrate for the epitaxial deposition of the second active region. When arranging on the first active region, the second active region is attached to the first active region via the connection region. The second active region is therefore not deposited on the same carrier on which the first active region has been deposited. The initial carrier can therefore be selected independently of the material of the first active region, for example with regard to a suitable crystal structure for the deposition of the second active region. The second photonic crystal can be formed before or after the second active region is attached to the first active region.

According to at least one embodiment of the method, the initial carrier is removed before the second active region is attached to the first active region. The second active region can be attached to the first active region such that the side of the second active region originally facing the initial carrier faces the first active region when attached to the first active region.

For example, the second active region is attached to a further carrier before the initial carrier is removed. The further carrier can therefore mechanically stabilize the second active region while it is attached to the first active region.

According to at least one embodiment of the method, the connection region comprises a TCO material. In particular, a first sublayer of the connection region is formed on the first active region and a second sublayer of the connection region is formed on the second active region, so that when the second active region is arranged on the first active region, the first sublayer and the second sublayer are bonded to each other. For example, a direct bond connection is formed between the first sublayer and the second sublayer.

In a direct bond connection, the bonding partners to be joined together, for example the first sublayer and the second sublayer, are joined together in a mechanically stable manner via hydrogen bonds or van der Waals interactions. A joining layer such as an adhesive layer is not required for this.

A mechanically stable, electrically conducting and, in particular, optically transparent connection in the visible spectral range can be formed by a direct bond connection between two sublayers, each comprising a TCO material or consisting of such a material.

If necessary, the first sublayer and/or the second sublayer can be planarized before bonding.

In principle, however, other electrically conductive types of connection can also be made as long as the connection comprises sufficient optical transmission for the radiation to be generated in the semiconductor laser.

According to at least one embodiment of the method, the connection region is a tunnel junction, wherein the second active region is deposited on the tunnel junction. The arrangement of the second active region on the first active region is thus carried out in this case by an epitaxial deposition of the second active region on the first active region, in particular. The epitaxial deposition of the first active region and the second active region can therefore take place on the same growth substrate.

In particular, the second active region is deposited after the first photonic crystal has been formed.

The first photonic crystal and/or the second photonic crystal can be produced, for example, by means of a wet chemical or dry chemical etching process.

After etching, the semiconductor material structured in this way can be epitaxially overgrown to form the second active region.

According to at least one embodiment of the method, the first active region is provided on a carrier and the carrier is removed after the second active region is arranged on the first active region. For example, the carrier is a growth substrate for the epitaxial deposition of the first active region. The carrier and/or the initial carrier can be removed, for example, by means of a laser lift-off (LLO) process, chemically, for example by means of electrochemical etching, and/or mechanically, for example by means of grinding or polishing.

Further configurations and expediencies are apparent from the following description of the exemplary embodiments in conjunction with the figures.

### BRIEF DESCRIPTION OF THE DRAWINGS

FIG. 1 shows a schematic sectional view of an exemplary embodiment of a semiconductor laser;

FIG. 2 shows a schematic sectional view of an exemplary embodiment of a semiconductor laser;

FIGS. 3A to 3G show an exemplary embodiment of a method for manufacturing a semiconductor laser by means of intermediate steps each shown in schematic sectional view;

FIGS. 4A to 4H show an exemplary embodiment of a method for manufacturing a semiconductor laser by means of intermediate steps each shown in schematic sectional view; and

FIGS. 5A to 5E show an exemplary embodiment of a method for manufacturing a semiconductor laser by means of intermediate steps each shown in schematic sectional view.

Elements that are identical, similar or have the same effect are marked with the same reference symbols in the figures.

The figures are schematic representations and are therefore not necessarily true to scale. Rather, individual elements and in particular layer thicknesses may be exaggerated for improved understanding or better representability.

### DETAILED DESCRIPTION

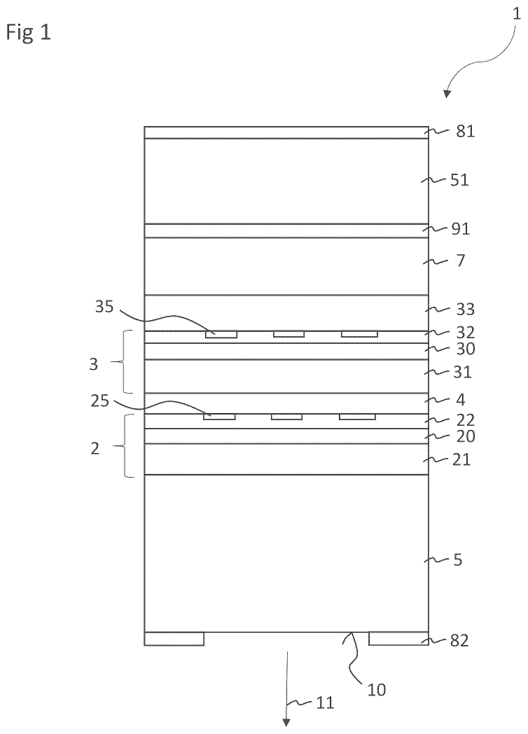

FIG. 1 illustrates an exemplary embodiment of a semiconductor laser 1 with a vertical emission direction 11. The semiconductor laser 1 comprises a first active region 20 and a photonic crystal 25. During operation of the semiconductor laser 1, first radiation emitted in the first active region 20 is partially deflected in the vertical emission direction 11 by means of the first photonic crystal 25.

The semiconductor laser further comprises a second active region 30 and a second photonic crystal 35, wherein second radiation emitted in the second active region 30 during operation of the semiconductor laser is partially deflected in the vertical emission direction 11 by means of the second photonic crystal 35. A connection region 4 of the semiconductor laser 1 is arranged between the first active region 20 and the second active region 30, the connection region 4 electrically conducting the first active region 20 and the second active region 30 to each other.

The first active region 20 is located between a first n-conducting semiconductor layer 21 and a first p-conducting semiconductor layer 22. The first n-conducting semiconductor layer 21 and the first p-conducting semiconductor layer 22 are part of a first waveguide 2, in which the first radiation generated in the first active region 20 during operation propagates in a lateral direction, i.e. perpendicular to the vertical emission direction 11.

The first photonic crystal 25 is located within the first waveguide 2, so that the radiation propagating in the lateral direction interacts with the first photonic crystal and is deflected in the vertical emission direction 11.

Accordingly, the second active region 30 is located between a second n-conducting layer 31 and a second p-conducting layer 32. A second waveguide 3 is formed by means of the second n-conducting layer 31 and the second p-conducting layer 32, in which the radiation generated in the second active region 30 propagates in the lateral direction.

The first photonic crystal 25 may be located entirely within or only partially within the first p-conducting semiconductor layer 22 or within the first n-conducting semiconductor layer 21. However, the first photonic crystal 25 may also be located outside the first n-conducting semiconductor layer 21 and outside the first p-conducting semiconductor layer 22 as long as there is sufficient interaction between the first radiation propagating in the lateral direction in the first waveguide 2 and the first photonic crystal 25. The second photonic crystal 35 may be located entirely within or only partially within the second p-conducting semiconductor layer 32 or within the second n-conducting semiconductor layer 31. However, the second photonic crystal 35 may also be located outside the second n-conducting semiconductor layer 31 and outside the second p-conducting semiconductor layer 32 as long as there is sufficient interaction between the second radiation propagating in the lateral direction in the second waveguide 3 and the second photonic crystal 25.

The connection region 4 is located between the first waveguide 2 and the second waveguide 3. This reduces the optical coupling between the first waveguide 2 and the second waveguide 3. Thus, the first active region 20 and the second active region 30 are each located in a separate waveguide.

Viewed along the vertical emission direction 11, the first active region 20 and the second active region 30 are located between a radiation exit surface 10 and a reflector 7. The reflector 7 is formed, for example, by a Bragg reflector, a metal reflector or a combination thereof. For example, the reflector comprises a reflectivity of at least 90% or at least 95% or at least 99%. Preferably, no reflector is arranged on the side of the reflector 7 facing away from the first active region 20. Optionally, an anti-reflective coating can be arranged on the radiation exit surface 10 to reduce reflection (not explicitly shown in FIG. 1).

In the exemplary embodiment shown, the radiation exit surface 10 is formed by a carrier 5 on which the first active region 20 is arranged. For example, the carrier is a growth substrate for the epitaxial deposition of the first active region 20.

The carrier 5 is transmissive to the first radiation and to the second radiation.

A further carrier 51 is arranged on the side of the reflector 7 facing away from the radiation exit surface 10. The further carrier 51 is located outside the beam path of the first radiation and the second radiation and can therefore be selected largely independently of its optical properties, for example with regard to its electric conductivity, processability or cost-effective availability.

A first contact 81 for external electrical contacting of the semiconductor laser is arranged on the further carrier 51. The first contact 81 may extend over large areas or over the entire surface of the further carrier 51.

A second contact 82 is arranged on the radiation exit surface 10. By applying an electrical voltage between the first contact 81 and the second contact 82, charge carriers can be injected from opposite sides into the first active region 20 and the second active region 30 and recombine there, emitting first radiation and second radiation respectively.

The second contact 82 is ring-shaped or frame-shaped, for example. For improved current spreading in the lateral direction, the radiation exit surface 10 can be formed by a current spreading layer, which is arranged on the carrier 5 and electrically conductively connected to the second contact 82. For example, the current spreading layer contains a TCO material. Such a current spreading layer can be arranged across large areas or over the entire surface of the radiation exit surface 10.

The reflector 7 is electrically conductively connected to the further carrier 51 via a joining layer 91, for example a solder layer or an electrically conductive adhesive layer.

A connecting layer 33 is arranged between the second p-conducting semiconductor layer 32 and the reflector 7. The connecting layer 33 can contain a semiconductor material or a TCO material. In particular, the distance of the second active region 30 from the reflector 7 can be adjusted via the thickness of the connecting layer 33.

During operation of the semiconductor laser 1, a standing wave field can form along the vertical emission direction 11. The connection region 4 is preferably arranged such that it is located in a minimum of the standing wave field. This allows absorption losses in the connection region 4 to be reduced.

The connection region 4 can be a TCO material or a tunnel transition.

The first active region 20 and the second active region 30 are arranged parallel and not antiparallel to each other with respect to their forward direction. An electrical series connection of the first active region 20 and the second active region 30 and a common electrical contacting via the first contact 81 and the second contact 82 are thus simplified.

For example, the first n-conducting semiconductor layer 21 is arranged between the first active region 20 and the radiation exit surface 10 and the second n-conducting semiconductor layer 31 is arranged between the second active region 30 and the radiation exit surface 10.

Alternatively, these n-conducting semiconductor layers 21, 31 can also be arranged on the side of the associated active region facing away from the radiation exit surface.

Deviating from the illustration shown in FIG. 1, a third contact may also be present, which electrically contacts the semiconductor laser 1 between the first active region 20 and the second active region 30. The active regions 20 and 30 can thus be controlled independently of each other and, for example, supplied with different operating currents or operating voltages.

The first active region 20 and the second active region 30 can be formed in the same way, so that the peak wavelengths of the first radiation and the second radiation do not differ or differ only slightly from one another. Furthermore, the first photonic crystal 25 and the second photonic crystal 35 can also be formed of the same type.

This can result in particularly effective operation of the semiconductor laser, in which mode coupling occurs between the first radiation and the second radiation.

Deviating from this, the first active region 20 and the second active region 30 may also differ from each other in a targeted manner, so that the first radiation and the second radiation comprise different peak wavelengths from each other. In this case, a semiconductor laser 1 can thus be provided in which radiation components with different peak wavelengths exit from the same radiation exit surface 10, wherein the radiation components can exit from the radiation exit surface 10 at least partially or completely overlapping.

Particularly large differences between the peak wavelengths of the first radiation and the second radiation can be achieved if the active regions 20, 30 are based on semiconductor material systems different from each other. For example, the first active region 20 may be based on a nitride compound semiconductor material and configured to generate radiation in the ultraviolet or blue spectral range, while the second active region 30 is based on arsenide or phosphide compound semiconductor material and configured to generate radiation in the green, orange, red or infrared spectral range.

Alternatively or additionally, the semiconductor laser 1 can be designed in such a way that the first radiation and the second radiation differ from each other along the vertical emission direction with respect to their polarization direction. For this purpose, for example, the first photonic crystal 25 and the second photonic crystal 35 can be structured in such a way that different preferred directions for polarization are set for the first radiation and the second radiation.

By stacking the first active region 20 and the second active region 30 along the vertical emission direction 11 as described, the optical power density of the total generated radiation can be increased. In principle, more than two active regions 20, 30 can also be stacked on top of each other along the vertical emission direction 11.

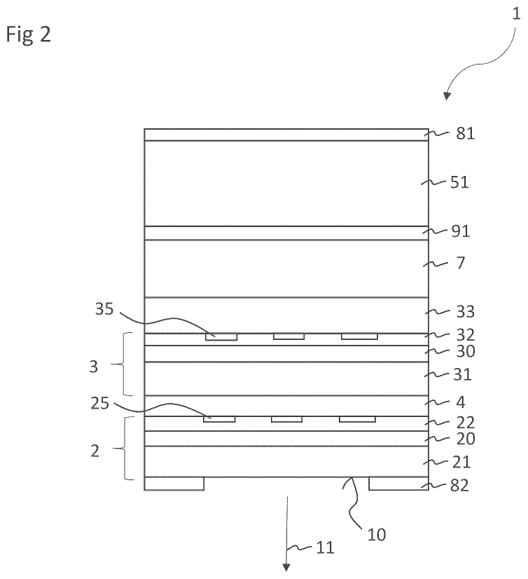

The exemplary embodiment illustrated in FIG. 2 essentially corresponds to the exemplary embodiment described in connection with FIG. 1. In contrast, the carrier 5 is removed so that the radiation exit surface 10 is formed by the first n-conducting semiconductor layer 21. In this case, the additional carrier 51 acts as a mechanically stabilizing element of the semiconductor laser 1. The growth substrate on which the epitaxial deposition of the semiconductor layers of the first waveguide 2 took place is therefore no longer present in the semiconductor laser 1. A material that is not transmissive and/or not electrically conductive for the radiation to be generated in the semiconductor laser 1 can thus also be used for the epitaxial deposition.

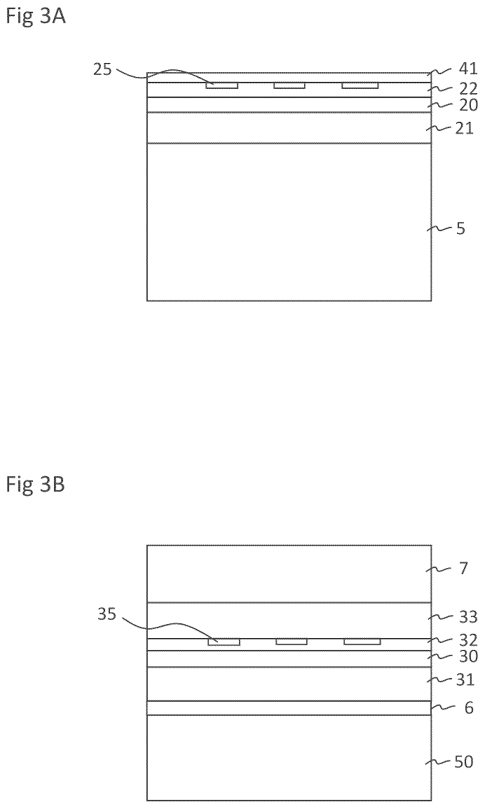

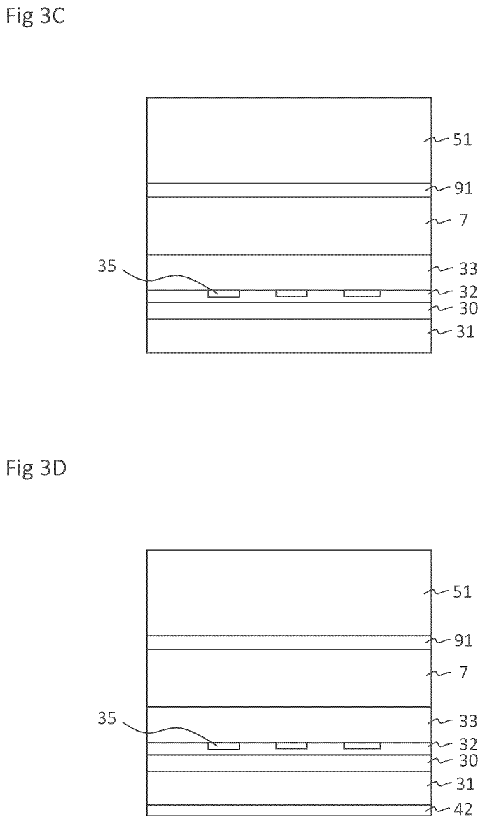

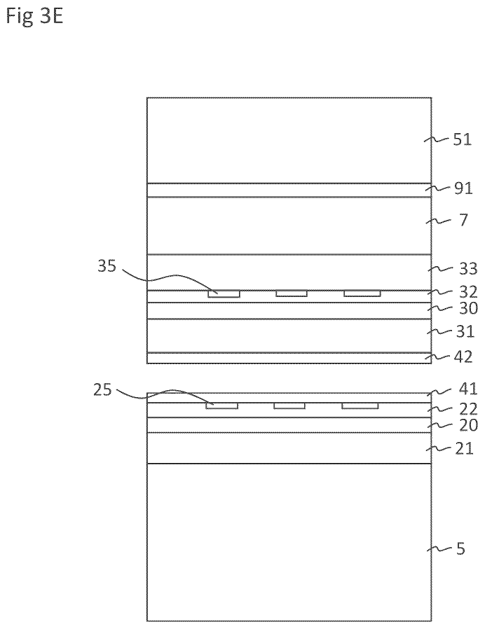

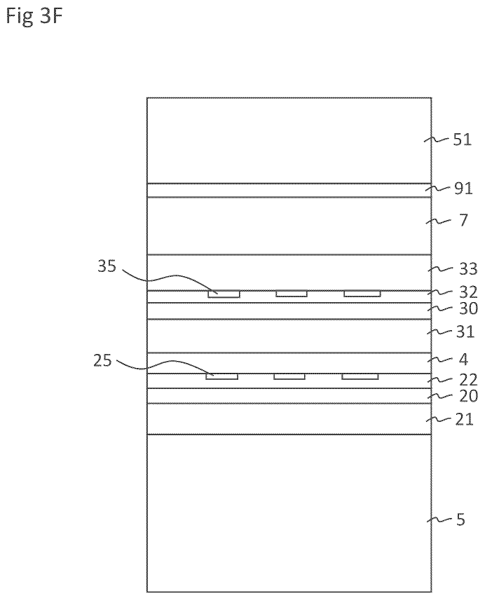

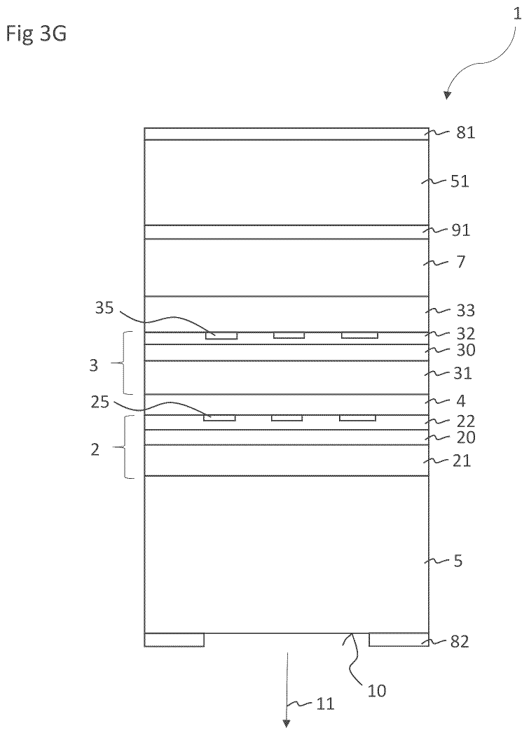

FIGS. 3A to 3G illustrate an exemplary embodiment of a method for manufacturing a semiconductor laser. For the sake of simplicity, only one area is shown from which a semiconductor laser 1 emerges during production. With the method described, however, a large number of semiconductor lasers can be manufactured simultaneously and generated by, for example, final singulation.

As shown in FIG. 3A, a first active region 20 is provided on a carrier 5, for example a growth substrate. The first active region 20 is located between a first n-conducting semiconductor layer 21 and a first p-conducting semiconductor layer 22. A first photonic crystal 25 is disposed on the first active region 20. The first photonic crystal 25 may be formed in the first p-conducting semiconductor layer 22 or outside the second p-conducting semiconductor layer 22. A first sublayer 41 of a connection region formed in a later step is disposed on the first p-conducting semiconductor layer 22.

As shown in FIG. 3B, a second active region 30 is formed on an initial carrier 50. For example, the initial carrier 50 is a growth substrate for epitaxial deposition of the second active region 30. The second active region 30 is located between a second n-conducting semiconductor layer 31 and a second p-conducting semiconductor layer 32. A second photonic crystal 35 is associated with the second active region 30. The second photonic crystal 35 may be formed completely or partially in the second p-conducting semiconductor layer 32 or completely or partially in a connecting layer 33 arranged on the second p-conducting semiconductor layer 32.

A reflector 7 is arranged on a side of the second active region 30 facing away from the initial carrier 30.

The first photonic crystal 25 and the second photonic crystal 35 are formed on the side of the associated first active region 20 or second active region 30 facing away from the respective growth substrate. Both the first active region 20 and the second active region 30 are thus deposited on the respective growth substrate before structuring for the formation of the respective associated photonic crystal takes place. In this way, a high crystal quality can be reliably achieved for both active regions 20, 30.

As shown in FIG. 3C, the reflector 7 is attached to a further carrier 51 via a joining layer 91. The initial carrier 50 is removed, for example by dissolving a sacrificial layer 6 (see FIG. 3B).

A second sublayer 42 of a connection region is applied to the second n-conducting semiconductor layer 31 exposed in this way (FIG. 3D).

As shown in FIG. 3E, the first active region 20 and the second active region 30 are attached to each other with the first sublayer 41 and the second sublayer 42 facing each other and attached to each other by a bonding process, such as direct bonding, to form a connection region 4 (FIG. 3F).

Before making the bond connection, the first sublayer 41 and/or the second sublayer 42 can be planarized, for example by chemomechanical polishing.

The first active region 20 and the second active region 30 are arranged between a first contact 81 and a second contact 82. However, the first contact 81 and/or the second contact 82 can also be formed at an earlier stage of the process.

FIG. 3G shows the semiconductor laser 1 produced in this way, which is formed, for example, as described in connection with FIG. 1.

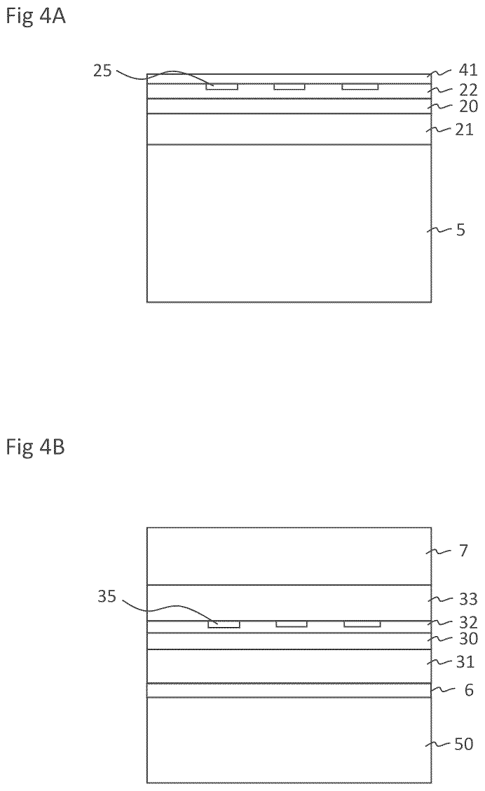

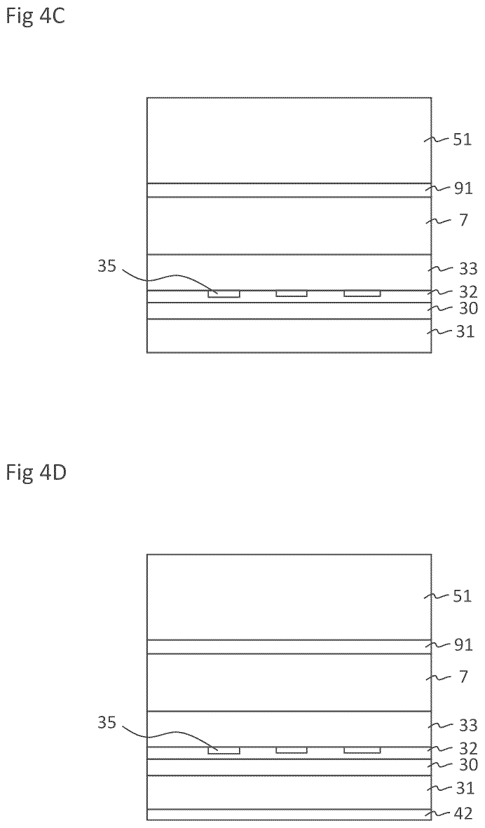

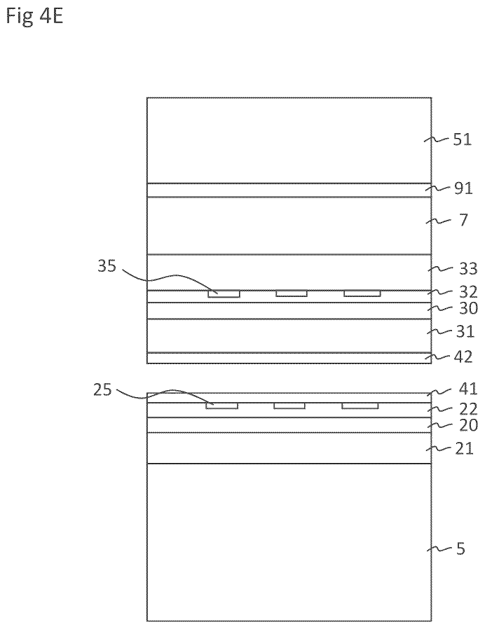

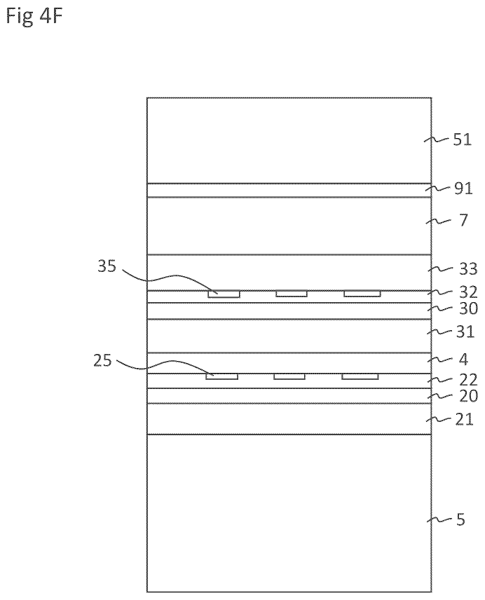

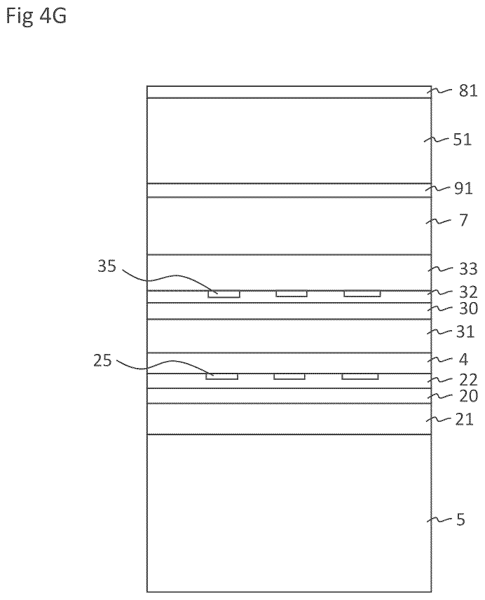

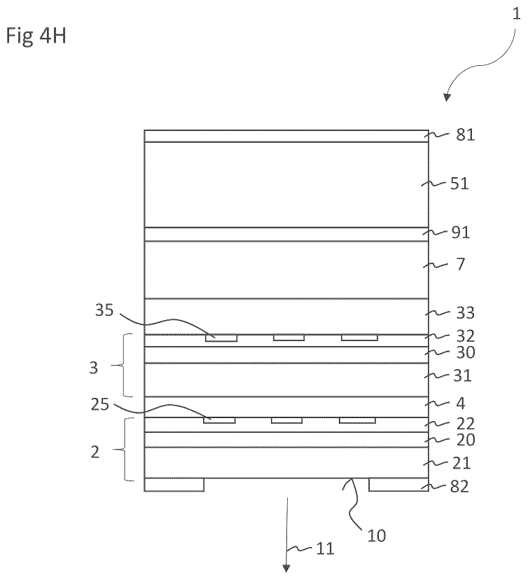

A further exemplary embodiment of a method is schematically illustrated with reference to FIGS. 4A to 4H. This method essentially corresponds to the exemplary embodiment illustrated in connection with FIGS. 3A to 3G.

In particular, the intermediate steps shown in FIGS. 4A to 4F are analogous to the intermediate steps shown in FIGS. 3A to 3F.

Subsequently, a first contact 81 is applied to the further carrier 51 (FIG. 4G).

The carrier 5 is removed. The second contact 82 is applied to the first n-conducting semiconductor layer 21 exposed in this way (FIG. 4H).

In this exemplary embodiment of the method, both the first active region 20 and the second active region 30 are thus separated from their original growth substrate. Thus, both growth substrates can be selected independently of their optical properties and their electrical properties. For example, sapphire can be used as a growth substrate for active regions based on nitride semiconductor compound material.

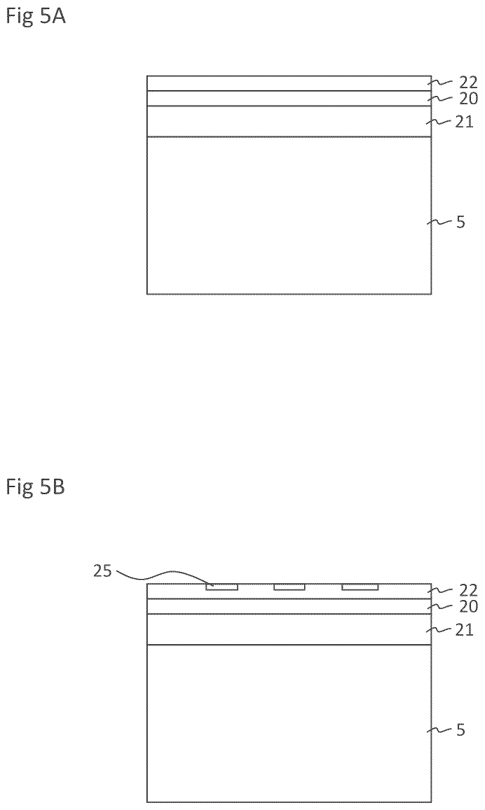

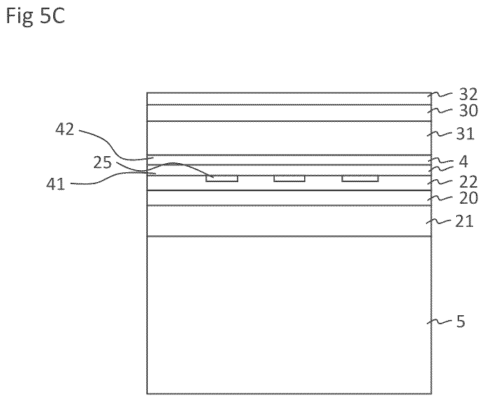

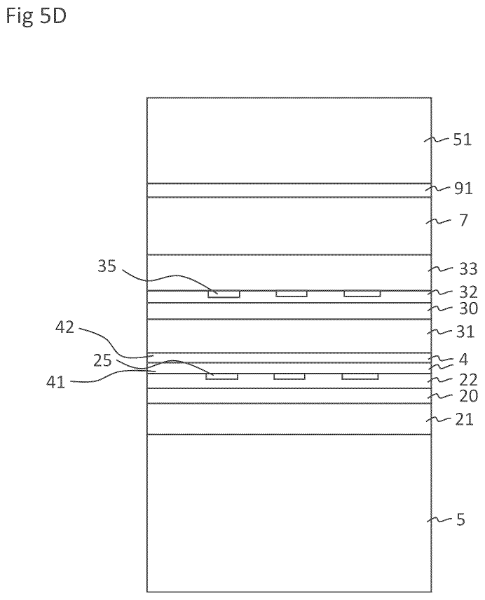

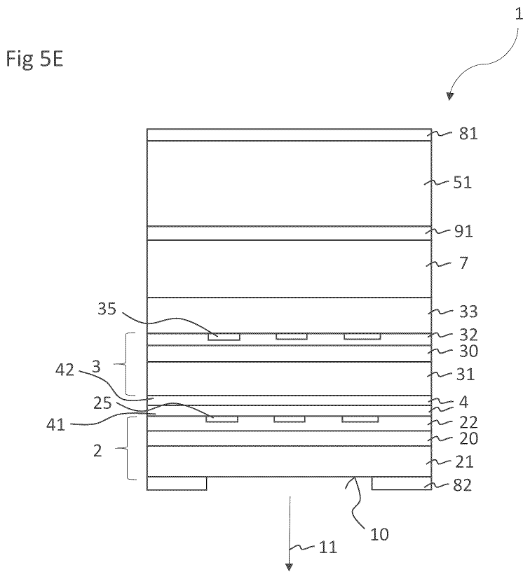

Another exemplary embodiment of a method for manufacturing a semiconductor laser is shown schematically with reference to FIGS. 5A to 5E.

This exemplary embodiment differs from the two preceding exemplary embodiments in particular in that the first active region 20 and the second active region 30 are not produced separately on different carriers and subsequently joined together.

As shown in FIG. 5A, the first active region 20, the first n-conducting semiconductor layer 21 and the first p-conducting semiconductor layer 22 are epitaxially deposited on a carrier 5, for example a growth substrate. The first p-conducting semiconductor layer 22 is structured to form a first photonic crystal 25, for example by a wet-chemical or dry-chemical etching process. The first photonic crystal 25 is subsequently epitaxially overgrown to form a connection region 4 and a second active region 30 (FIG. 5C).

In this case, the connection region 4 is a tunnel junction in which a first sublayer 41 and a second sublayer 42 are each highly doped semiconductor layers of opposite conduction type to each other. For example, a doping concentration of the first sublayer 41 and/or the second sublayer 42 is at least 1*10¹⁹ cm⁻³ or at least 1*10²⁰ cm⁻³ The active regions 20, 30 can be electrically connected in series to one another via this tunnel junction.

As shown in FIG. 5D, a connecting layer 33 and a reflector 7 are subsequently applied as described in connection with the preceding exemplary embodiments. The reflector 7 is attached to another carrier 51 via a joining layer 91.

As shown in FIG. 5E, the carrier 5 is removed and the first contact 81 and the second contact 82 are applied. The finished semiconductor laser is shown in FIG. 5E.

In contrast to the illustration in FIG. 5E, the carrier 5 can also remain in the semiconductor laser 1 as shown in FIG. 1.

The methods described can be used to reliably stack active regions on top of each other along the vertical emission direction, allowing a semiconductor laser with increased optical power density to be reliably produced.

This patent application claims the priority of the German patent application 10 2021 133 904.9, the disclosure of which is hereby incorporated by reference.

The invention is not limited by the description based on the exemplary embodiments. Rather, the invention includes any new feature as well as any combination of features, which includes in particular any combination of features in the patent claims, even if this feature or combination itself is not explicitly stated in the patent claims or the exemplary embodiments.

1. A semiconductor laser having a vertical emission direction comprising:
a first active region and a first photonic crystal, wherein a first radiation emitted in the first active region during operation of the semiconductor laser is partially deflected in the vertical emission direction by the first photonic crystal;
a second active region and a second photonic crystal, wherein a second radiation emitted in the second active region during operation of the semiconductor laser is partially deflected in the vertical emission direction by the second photonic crystal; and
a connection region, which is arranged in the vertical emission direction between the first active region and the second active region and electrically conductively connects the first active region and the second active region to one another.

2. The semiconductor laser according to claim 1, in which a forward direction of the first active region and a forward direction of the second active region point in the same direction.

3. The semiconductor laser according to claim 1, in which the first active region and the second active region are of the same type.

4. The semiconductor laser according to claim 1, in which the first photonic crystal and the second photonic crystal are formed in the same way.

5. The semiconductor laser according to claim 1, in which the first radiation and the second radiation differ from each other along the vertical emission direction with respect to their polarization direction.

6. The semiconductor laser according to claim 1, in which the first active region and the second active region differ from each other with respect to a material composition.

7. The semiconductor laser according to claim 1, in which the connection region is a tunnel transition or comprises a TCO material.

8. The semiconductor laser according to claim 1, in which, during operation of the semiconductor laser, a standing wave field is formed in the vertical emission direction, the connection region being arranged in a minimum of the standing wave field.

9. The semiconductor laser according to claim 1, in which the first radiation propagates in a lateral direction in a first waveguide and the second radiation propagates in the lateral direction in a second waveguide.

10. A method of manufacturing a semiconductor laser comprising:
a) providing a first active region and a first photonic crystal; and
b) arranging a second active region and a second photonic crystal on the first active region, a connection region electrically conducting the first active region and the second active region being arranged between the first active region and the second active region.

11. The method according to claim 10, in which the second active region is deposited separately from the first active region on an initial carrier and is attached to the first active region via the connection region in step b).

12. The method according to claim 11, in which the initial carrier is removed before the second active region is attached to the first active region.

13. The method according to claim 10, in which the connection region contains a TCO material and in step b) a first sublayer of the connection region on the first active region and a second sublayer of the connection region on the second active region are bonded to one another.

14. The method according to claim 10, in which the connection region is a tunnel junction and the second active region is deposited on the tunnel junction in step b).

15. The method according to claim 10, in which the first active region is provided on a carrier in step a) and the carrier is removed after step b).

16. A method of manufacturing the semiconductor laser according to claim 1 comprising:
providing a first active region and a first photonic crystal; and
arranging a second active region and a second photonic crystal on the first active region, a connection region electrically conducting the first active region and the second active region being arranged between the first active region and the second active region.

17. A semiconductor laser having a vertical emission direction comprising:
a first active region and a first photonic crystal, wherein a first radiation emitted in the first active region during operation of the semiconductor laser is partially deflected in the vertical emission direction by the first photonic crystal;
a second active region and a second photonic crystal, wherein a second radiation emitted in the second active region during operation of the semiconductor laser is partially deflected in the vertical emission direction by the second photonic crystal; and
a connection region, which is arranged in the vertical emission direction between the first active region and the second active region and electrically conductively connects the first active region and the second active region to one another;
wherein the first radiation propagates in a lateral direction in a first waveguide and the second radiation propagates in the lateral direction in a second waveguide.
